(19) United States
(12) Patent Application Publication
(10) Pub. No.: US 2024/0047386 A1
(43) Pub. Date: Feb. 8, 2024

(54) Semiconductor Device and Method of Forming Hybrid Substrate with IPD Over Active Semiconductor Wafer

(71) Applicant: STATS ChipPAC Pte. Ltd., Singapore (SG)

(72) Inventors: YongTaek Lee, Seoul (KR); OhYoung Kwon, Seoul (KR); SeungMan Hong, Seoul (KR)

(73) Assignee: STATS ChipPAC Pte. Ltd., Singapore (SG)

(21) Appl. No.: 17/817,089

(22) Filed: Aug. 3, 2022

(51) Int. Cl. H01L 23/64; H01L 23/00; H01L 21/822

(52) U.S. Cl. CPC H01L 23/647; H01L 24/48; H01L 24/16; H01L 24/73; H01L 21/822; H01L 2224/48227; H01L 2224/16227; H01L 2224/73257; H01L 28/10

(57) ABSTRACT

A semiconductor device has a semiconductor wafer with a plurality of semiconductor die. The semiconductor wafer has a low resistivity. An insulating layer is formed over the semiconductor wafer. A first IPD is formed over the insulating layer. The first IPD can be a capacitor, resistor, or inductor. A second IPD is formed over a second surface of the semiconductor wafer opposite the first surface of the semiconductor wafer. An interconnect structure is formed over the first IPD. An interconnect substrate is provided with the semiconductor die disposed over the interconnect substrate. A bond wire is formed between the interconnect structure and the interconnect substrate. Alternatively, an active device is formed in a second surface of the semiconductor die opposite the first surface of the semiconductor die. The semiconductor die incorporates the hybrid substrate to allow IPD and active devices to be formed from a single substrate.

### FIELD OF THE INVENTION

The present invention relates in general to semiconductor devices and, more particularly, to a semiconductor device and method of forming a hybrid substrate with an IPD over an active area on a semiconductor wafer.

### BACKGROUND OF THE INVENTION

Semiconductor devices are commonly found in modern electrical products. Semiconductor devices perform a wide range of functions, such as signal processing, high-speed calculations, transmitting and receiving electromagnetic signals, controlling electrical devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices often contain a semiconductor die and one or more integrated passive devices (IPDs) to perform necessary electrical functions. For example, a flip-chip die and wire-bond IPD are manufactured using two wafers because the two processes are different. MOS silicon wafers with low-resistivity silicon (Si) are used as active devices, and high-resistivity Si wafers are used for IPDs to improve electrical characteristics. Since the active die and the wire bond IPD die use different Si wafers, a high-resistance silicon wafer is required for additional IPD fabrication. The active die and the wire bond IPD die can be stacked or side-by-side. The additional wafer(s) needed to form both active devices and IPDs increases manufacturing costs.

### BRIEF DESCRIPTION OF THE DRAWINGS

FIGS. 1a-1c illustrate a first semiconductor wafer with a plurality of first semiconductor die separated by a saw street;

FIGS. 2a-2h illustrate a process of forming a hybrid substrate with IPDs on opposite sides of an active semiconductor wafer;

FIGS. 3a-3e illustrate disposing the hybrid substrate with IPD of FIGS. 2a-2h in a semiconductor package;

FIGS. 4a-4e illustrate another process of forming a hybrid substrate with IPD on one side of an active semiconductor wafer;

FIGS. 5a-5e illustrate disposing the hybrid substrate with IPD of FIGS. 4a-4e in a semiconductor package; and

FIG. 6 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

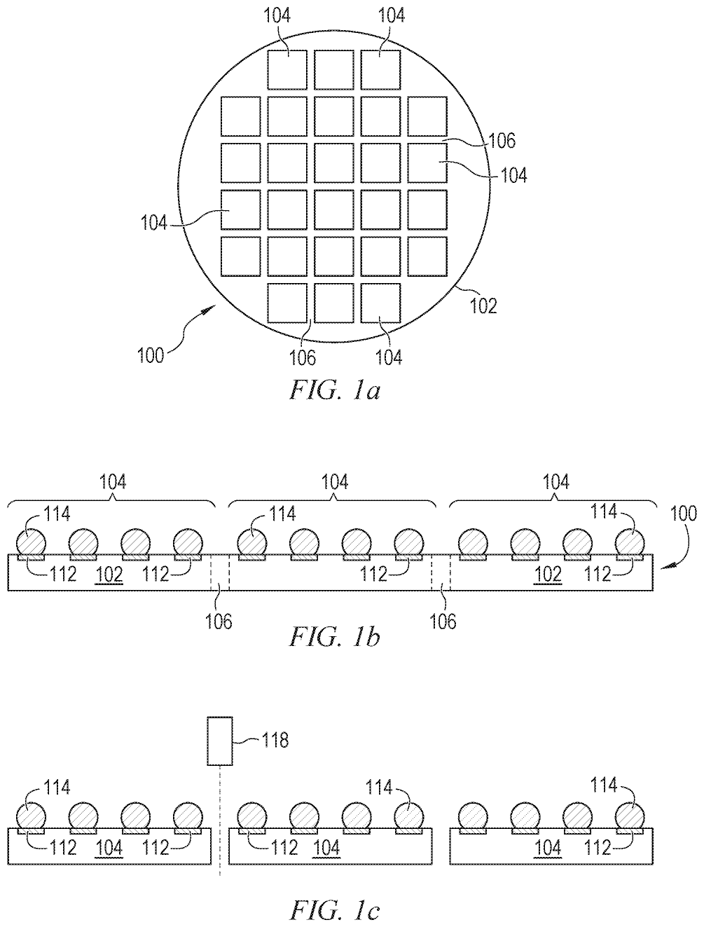

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1B shows a cross-sectional view of a portion of semiconductor wafer 100. An electrically conductive layer 112 is formed using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

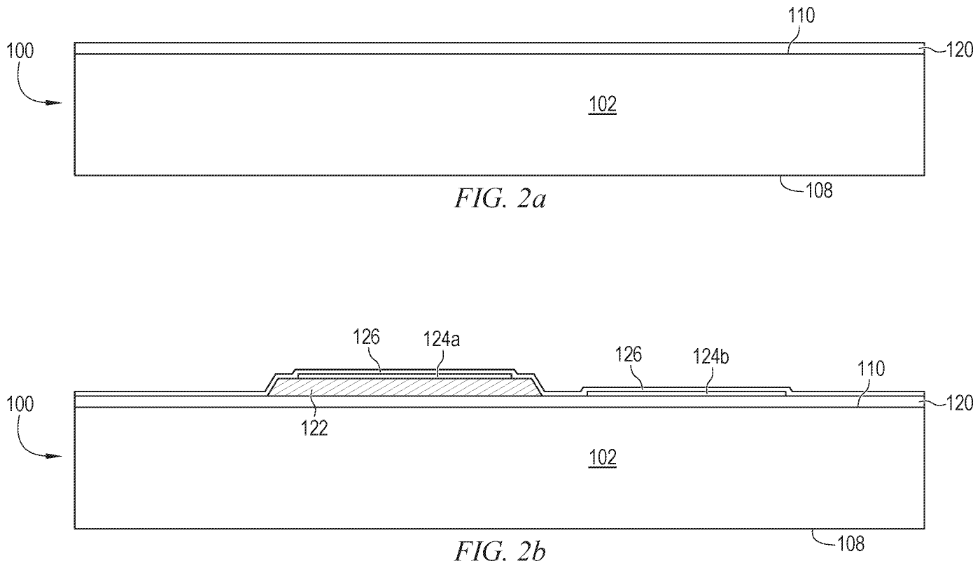

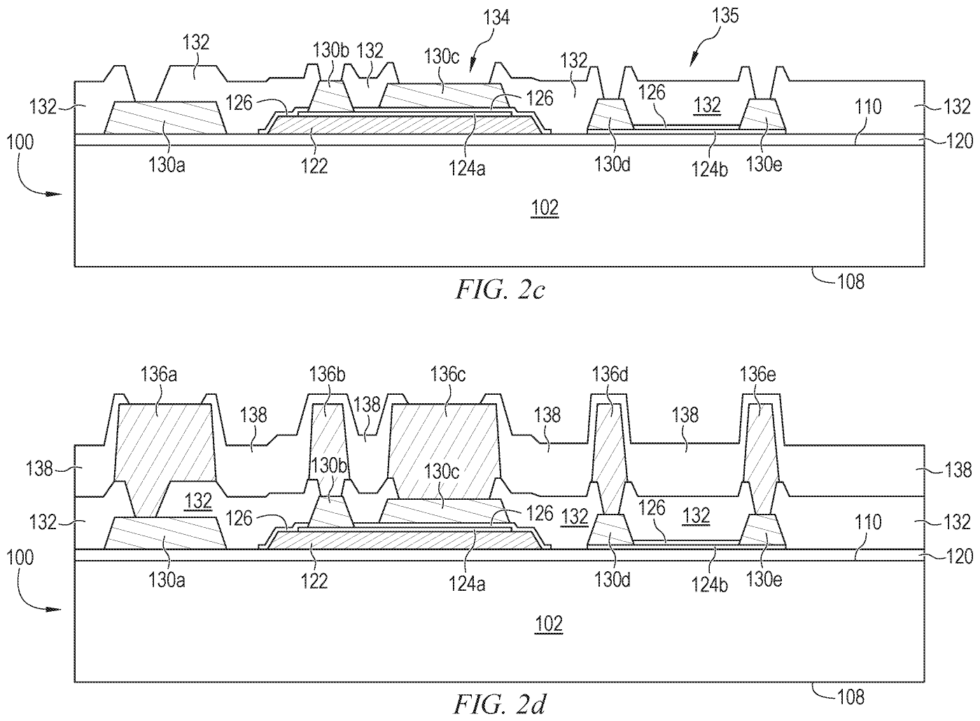

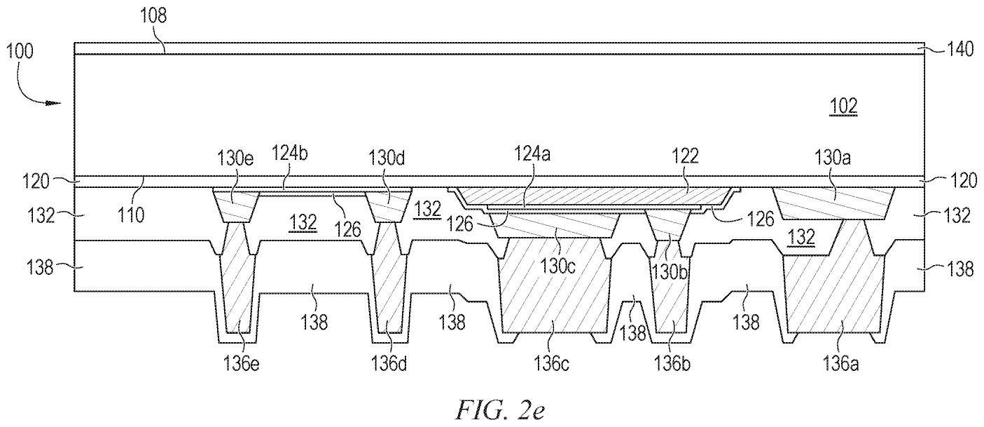

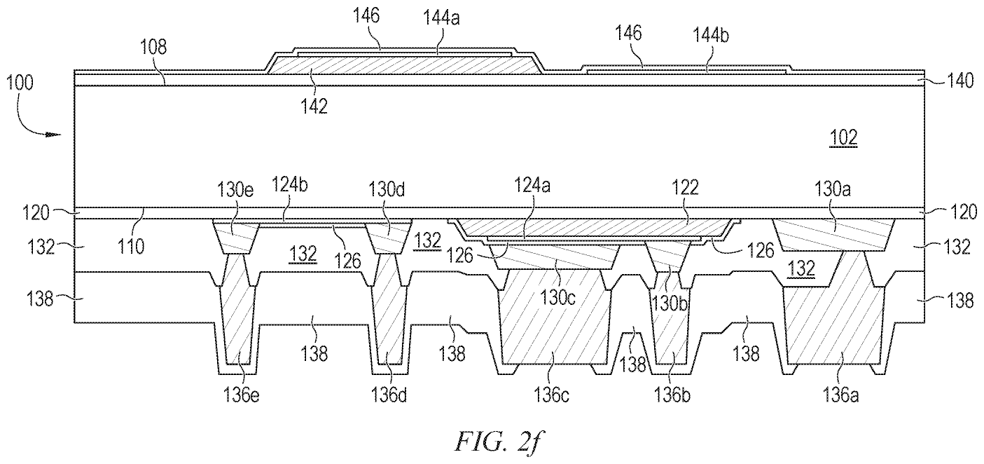

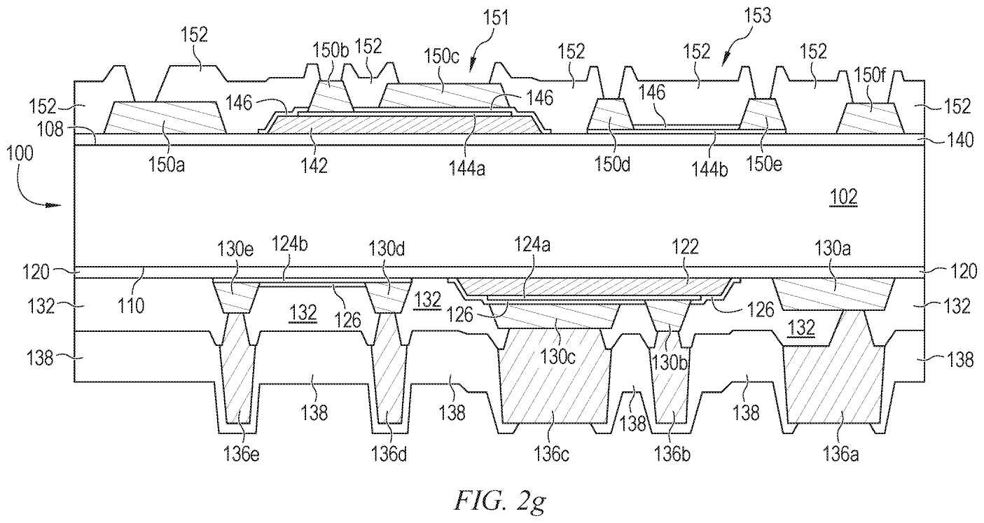

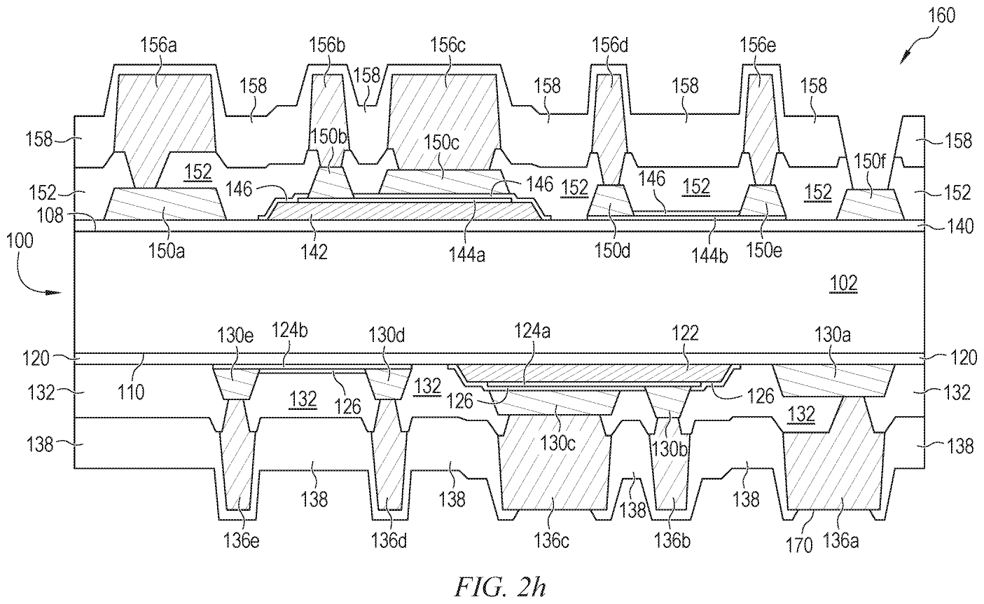

FIG. 2a shows a portion of semiconductor wafer 100 from FIG. 1a within one semiconductor die 104. Each semiconductor die 104 has a first surface 108 and a second surface 110. Either surface 108 and/or 110 may contain analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within surface 108 or 110 to implement analog circuits or digital circuits, such as digital signal processor (DSP), application specific integrated circuits (ASIC), memory, or other signal processing circuit.

An insulating or passivation layer 120 is formed over surface 110 using PVD, CVD, printing, lamination, spin coating, spray coating, sintering or thermal oxidation. Insulating layer 120 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. In one embodiment, insulating layer 120 is oxide. Insulating layer 120 provides isolation from surface 110.

In FIG. 2b, conductive layer 122 is formed over insulating layer 120 and surface 110 of semiconductor wafer 100 using PVD, CVD, electrolytic plating, electroless plating process, or other suitable metal deposition process. Conductive layer 122 can be one or more layers of Al, Cu, Sn, Ni, Au, Ag, or other suitable electrically conductive material. Conductive layer 122 operates as a method capacitor (M-cap) base layer, i.e., a bottom electrode of subsequently formed capacitor.

A resistive layer 124 is formed over conductive layer 122 and insulating layer 120. Resistive layer 124 can be tantalum silicide (TaSi2) or other metal silicides, TaN, nichrome (NiCr), TiN, or doped poly-silicon. The deposition of resistive layer 124 may involve PVD or CVD with a thicknesses matching a designed surface resistivity (Rs). Portions of resistive layer 124 are removed, leaving resistive layer 124a and 124b, as shown.

An insulating or passivation layer 126 is formed over insulating layer 120, conductive layer 122, and resistive layer 124 using PVD, CVD, printing, lamination, spin coating, spray coating, sintering or thermal oxidation. Insulating layer 126 contains one or more layers of SiO2, Si3N4, SiON, Ta2O5, Al2O3, solder resist, polyimide, BCB, PBO, and other material having similar insulating and structural properties. In one embodiment, insulating layer 126 is nitride.

In FIG. 2c, portions of insulating layer 126 are removed to expose conductive layer 122 and insulating layer 120, as shown. Conductive layer 130 is formed over insulating layer 120, resistive layer 124, and insulating layer 126 using PVD, CVD, electrolytic plating, electroless plating process, or other suitable metal deposition process. Conductive layer 130 can be one or more layers of Al, Cu, Sn, Ni, Au, Ag, or other suitable electrically conductive material. Portions of conductive layer 130 can be electrically common or electrically isolated depending on the design and function of semiconductor die and other electrical components attached thereto. In particular, conductive layer 130a is formed over insulating layer 120, conductive layer 130b is formed over resistive layer 124a through an opening in insulating layer 126, conductive layer 130c is formed over insulating layer 126, and conductive layer 130d and 130e is formed over resistive layer 124b through an opening in insulating layer 126. The combination of conductive layer 130c, insulating layer 126, resistive layer 124a, and M-cap conductive layer 122 constitute capacitor or integrated passive device (IPD) 134. The combination of conductive layer 130d, resistive layer 124b, and conductive layer 130e constitute resistor 135. A portion of conductive layer 130 can be wound into a spiral to have inductive properties. Accordingly, one or more IPD are formed over or above surface 110 of semiconductor wafer 100.

An insulating or passivation layer 132 is formed over insulating layer 120 and conductive layer 130 using PVD, CVD, printing, lamination, spin coating, spray coating, sintering or thermal oxidation. Insulating layer 132 contains one or more layers of SiO2, Si3N4, SiON, Ta2O5, Al2O3, solder resist, polyimide, BCB, PBO, and other material having similar insulating and structural properties. Insulating layer 132 provides isolation around conductive layer 130. Portions of insulating layer 132 are removed to expose conductive layer 130 for further electrical interconnect.

In FIG. 2d, conductive layer 136 is formed over conductive layer 130 and insulating layer 132 using PVD, CVD, electrolytic plating, electroless plating process, or other suitable metal deposition process. Conductive layer 136 can be one or more layers of Al, Cu, Sn, Ni, Au, Ag, or other suitable electrically conductive material. Portions of conductive layer 136 can be electrically common or electrically isolated depending on the design and function of semiconductor die and other electrical components attached thereto. In particular, conductive layer 136a is formed over and electrically connected to conductive layer 130a, conductive layer 136b is formed over and electrically connected to conductive layer 130b, conductive layer 136c is formed over and electrically connected to conductive layer 130c, conductive layer 136d is formed over and electrically connected to conductive layer 130d, and conductive layer 136e is formed over and electrically connected to conductive layer 130e. Conductive layers 130 and 136 constitute an interconnect structure formed over IPD like 134 and 135 to provide electrical connection for the IPD, as well as any active circuits formed within surface 108 of wafer 100.

An insulating or passivation layer 138 is formed over insulating layer 132 and conductive layer 136 using PVD, CVD, printing, lamination, spin coating, spray coating, sintering or thermal oxidation. Insulating layer 138 contains one or more layers of SiO2, Si3N4, SiON, Ta2O5, Al2O3, solder resist, polyimide, BCB, PBO, and other material having similar insulating and structural properties. Insulating layer 138 provides isolation around conductive layer 136. Portions of insulating layer 138 are removed to expose conductive layer 136 for further electrical interconnect, e.g., conductive layer 136a and 136c. In FIG. 2e, the assembly is inverted and insulating or passivation layer 140 is formed over surface 108 of semiconductor wafer 100 using PVD, CVD, printing, lamination, spin coating, spray coating, sintering or thermal oxidation. Insulating layer 140 contains one or more layers of SiO2, Si3N4, SiON, Ta2O5, Al2O3, solder resist, polyimide, BCB, PBO, and other material having similar insulating and structural properties. In one embodiment, insulating layer 140 is oxide. Insulating layer 140 provides isolation from surface 108.

In FIG. 2f, conductive layer 142 is formed over insulating layer 140 and surface 108 of wafer 100 using PVD, CVD, electrolytic plating, electroless plating process, or other suitable metal deposition process. Conductive layer 142 can be one or more layers of Al, Cu, Sn, Ni, Au, Ag, or other suitable electrically conductive material. Conductive layer 142 operates as an M-cap base layer, i.e., a bottom electrode of subsequently formed capacitor.

A resistive layer 144 is formed over conductive layer 142 and insulating layer 140. Resistive layer 144 can be TaSi2 or other metal silicides, TaN, NiCr, TiN, or doped poly-silicon. The deposition of resistive layer 144 may involve PVD or CVD with a thicknesses matching a designed surface resistivity. Portions of resistive layer 144 are removed, leaving resistive layer 144a and 144b, as shown.

An insulating or passivation layer 146 is formed over insulating layer 140, conductive layer 142, and resistive layer 144 using PVD, CVD, printing, lamination, spin coating, spray coating, sintering or thermal oxidation. Insulating layer 146 contains one or more layers of SiO2, Si3N4, SiON, Ta2O5, Al2O3, solder resist, polyimide, BCB, PBO, and other material having similar insulating and structural properties. In one embodiment, insulating layer 146 is nitride.

In FIG. 2g, portions of insulating layer 146 are removed to expose conductive layer 142 and insulating layer 140, as shown. Conductive layer 150 is formed over insulating layer 140, resistive layer 144, and insulating layer 146 using PVD, CVD, electrolytic plating, electroless plating process, or other suitable metal deposition process. Conductive layer 150 can be one or more layers of Al, Cu, Sn, Ni, Au, Ag, or other suitable electrically conductive material. Portions of conductive layer 150 can be electrically common or electrically isolated depending on the design and function of semiconductor die and other electrical components attached thereto. In particular, conductive layer 150a is formed over insulating layer 140, conductive layer 150b is formed over resistive layer 144a through an opening in insulating layer 146, conductive layer 150c is formed over insulating layer 146, and conductive layer 150d and 150e is formed over resistive layer 144b through an opening in insulating layer 146. The combination of conductive layer 150c, insulating layer 146, resistive layer 144a, and M-cap conductive layer 142 constitute capacitor or IPD 151. The combination of conductive layer 150d, resistive layer 144b, and conductive layer 150e constitute resistor 153. A portion of conductive layer 150 can be wound into a spiral to have inductive properties. Accordingly, one or more IPD are formed over surface 108 of semiconductor wafer 100.

An insulating or passivation layer 152 is formed over insulating layer 140 and conductive layer 150 using PVD, CVD, printing, lamination, spin coating, spray coating, sintering or thermal oxidation. Insulating layer 152 contains one or more layers of SiO2, Si3N4, SiON, Ta2O5, Al2O3, solder resist, polyimide, BCB, PBO, and other material having similar insulating and structural properties. Insulating layer 152 provides isolation around conductive layer 150. Portions of insulating layer 152 are removed to expose conductive layer 150 for further electrical interconnect.

In FIG. 2h, conductive layer 156 is formed over conductive layer 150 and insulating layer 152 using PVD, CVD, electrolytic plating, electroless plating process, or other suitable metal deposition process. Conductive layer 156 can be one or more layers of Al, Cu, Sn, Ni, Au, Ag, or other suitable electrically conductive material. Portions of conductive layer 156 can be electrically common or electrically isolated depending on the design and function of semiconductor die and other electrical components attached thereto. In particular, conductive layer 156a is formed over and electrically connected to conductive layer 150a, conductive layer 156b is formed over and electrically connected to conductive layer 150b, conductive layer 156c is formed over and electrically connected to conductive layer 150c, conductive layer 156d is formed over and electrically connected to conductive layer 150d, and conductive layer 156e is formed over and electrically connected to conductive layer 150e.

An insulating or passivation layer 158 is formed over insulating layer 152 and conductive layer 156 using PVD, CVD, printing, lamination, spin coating, spray coating, sintering or thermal oxidation. Insulating layer 158 contains one or more layers of SiO2, Si3N4, SiON, Ta2O5, Al2O3, solder resist, polyimide, BCB, PBO, and other material having similar insulating and structural properties. Insulating layer 158 provides isolation around conductive layer 156. Portions of insulating layer 158 are removed to expose conductive layer 156 for further electrical interconnect. Conductive layers 150 and 156 constitute an interconnect structure formed over IPD like 151 and 153 to provide electrical connection for the IPD, as well as any active circuits formed within surface 110 of wafer 100.

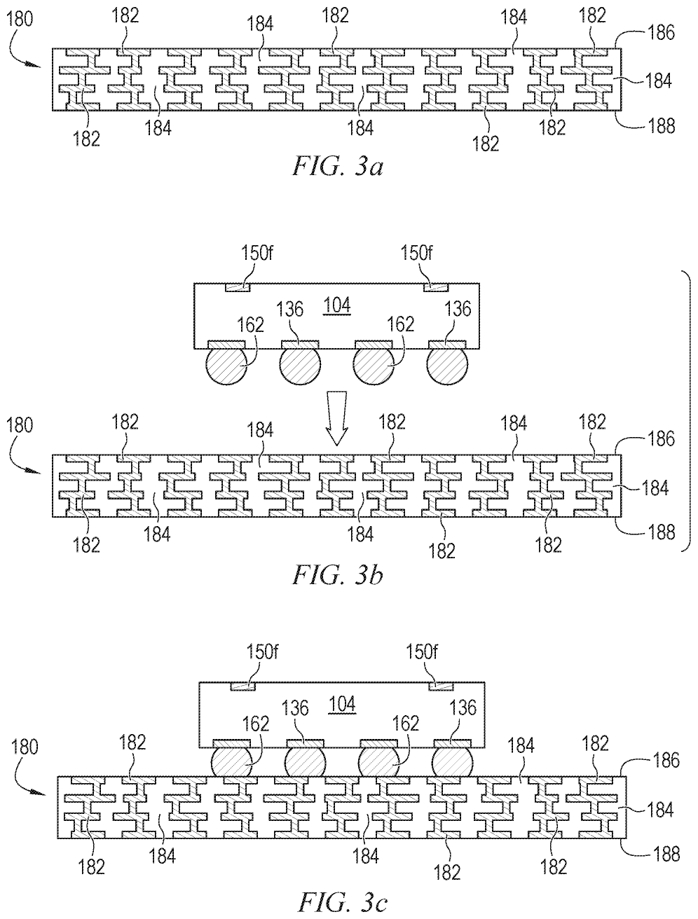

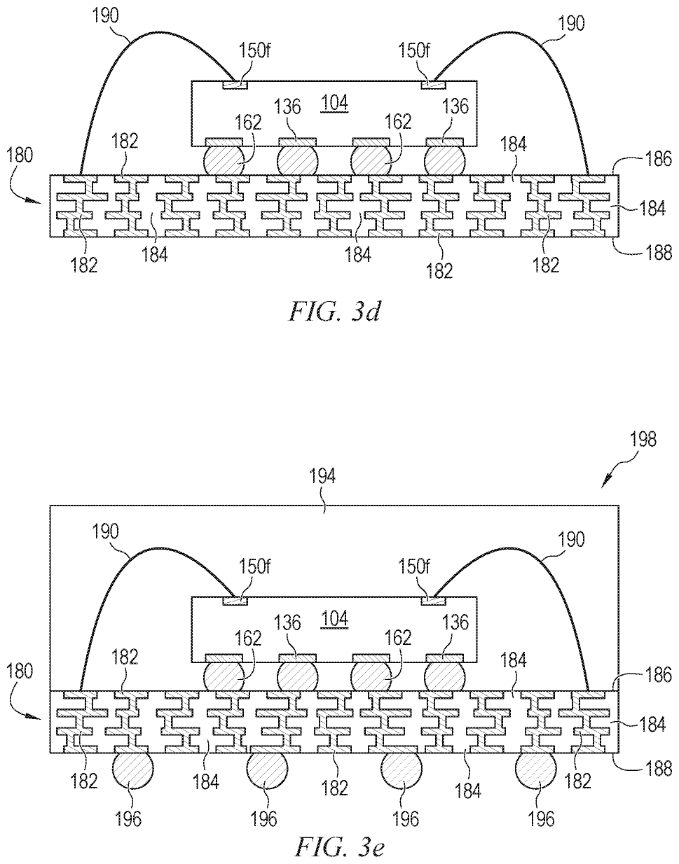

FIG. 3a shows a cross-sectional view of interconnect substrate 180 including conductive layers 182 and insulating layers 184. Conductive layers 182 can be one or more layers of Al, Cu, Sn, Ni, Au, Ag, or other suitable electrically conductive material. Conductive layers can be formed using PVD, CVD, electrolytic plating, electroless plating process, or other suitable metal deposition process. Conductive layers 182 provide horizontal electrical interconnect across substrate 180 and vertical electrical interconnect between top surface 186 and bottom surface 188 of substrate 180. Portions of conductive layers 182 can be electrically common or electrically isolated depending on the design and function of semiconductor die 104 and other electrical components. Insulating layers 184 contain one or more layers of SiO2, Si3N4, SiON, Ta2O5, Al2O3, solder resist, polyimide, BCB, PBO, and other material having similar insulating and structural properties. Insulating layers can be formed using PVD, CVD, printing, lamination, spin coating, spray coating, sintering or thermal oxidation. Insulating layers 184 provide isolation between conductive layers 182.

In FIG. 3b, semiconductor 104, similar to FIG. 1a, incorporates hybrid substrate 160 from FIG. 2h. That is, hybrid substrate 160 includes a single substrate 102 with active devices formed within the substrate and one or more IPDs formed over opposite sides of the hybrid substrate, as described in FIGS. 2a-2h.

Similar to FIG. 1B, an electrically conductive bump material is deposited over conductive layer 136, e.g., conductive layers 136a and 136c, using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 136 using a suitable attachment or bonding process. In one embodiment, the bump material is reflowed by heating the material above its melting point to form balls or bumps 162. In one embodiment, bump 162 is formed over a UBM having a wetting layer, barrier layer, and adhesive layer. Bump 162 can also be compression bonded or thermocompression bonded to conductive layer 136. Bump 162 represents one type of interconnect structure that can be formed over conductive layer 136. The interconnect structure can also use bond wires, conductive paste, stud bump, micro bump, or other electrical interconnect.

Similar to FIG. 1c, semiconductor wafer 100 is singulated through saw street 106 using a saw blade or laser cutting tool into individual semiconductor die 104 containing hybrid substrate 160. The individual semiconductor die 104 can be inspected and electrically tested for identification of known good die or known good unit (KGD/KGU) post singulation.

Semiconductor die 104, with IPD formed on opposite surfaces 108 and 110, is disposed on surface 186 of interconnect substrate 180 and electrically and mechanically connected to conductive layers 182. Semiconductor die 104 is positioned over substrate 180 using a pick and place operation with bumps 162 oriented toward surface 186 of substrate 180.

Semiconductor die 104 is brought into contact with surface 186 of interconnect substrate 180. FIG. 3c illustrates semiconductor die 104 electrically and mechanically connected to conductive layers 182 of substrate 180.

In FIG. 3d, bond wires 190 are attached between conductive layer 150f from FIG. 2h and conductive layer 182.

In 3e, an encapsulant or molding compound 194 is deposited over and around semiconductor die 104, bond wires 190, and interconnect substrate 180 using a paste printing, compressive molding, transfer molding, liquid encapsulant molding, vacuum lamination, spin coating, or other suitable applicator. Encapsulant 194 can be polymer composite material, such as epoxy resin with filler, epoxy acrylate with filler, or polymer with proper filler. Encapsulant 194 is non-conductive, provides structural support, and environmentally protects the semiconductor device from external elements and contaminants.

An electrically conductive bump material is deposited over conductive layer 182 on surface 188 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 182 using a suitable attachment or bonding process. In one embodiment, the bump material is reflowed by heating the material above its melting point to form balls or bumps 196. In one embodiment, bump 196 is formed over a UBM having a wetting layer, barrier layer, and adhesive layer. Bump 196 can also be compression bonded or thermocompression bonded to conductive layer 182. In one embodiment, bump 196 is a copper core bump for durability and maintaining its height. Bump 196 represents one type of interconnect structure that can be formed over conductive layer 182. The interconnect structure can also use bond wires, conductive paste, stud bump, micro bump, or other electrical interconnect.

The combination of interconnect substrate 180 and semiconductor die 104 containing hybrid substrate 160 constitute semiconductor package 198. Within semiconductor package 198, bond wires 190, conductive layers 150 and 156, interconnect substrate 180, and bumps 196 provide electrical interconnect for IPDs like 151 and 153 formed over surface 108 of semiconductor wafer 100, as well as active components within surface 108. Bumps 162, conductive layers 130 and 136, interconnect substrate 180, and bumps 196 provide electrical interconnect for IPDs like 134 and 135 formed over surface 110 of semiconductor wafer 100, as well as active components within surface 110. Hybrid substrate 160 in semiconductor package 198 uses one semiconductor wafer 100 to form IPDs on both sides of the wafer, thus reducing the number of wafers needed, as compared to the prior art described in the background. The single wafer to form IPDs reduces manufacturing costs.

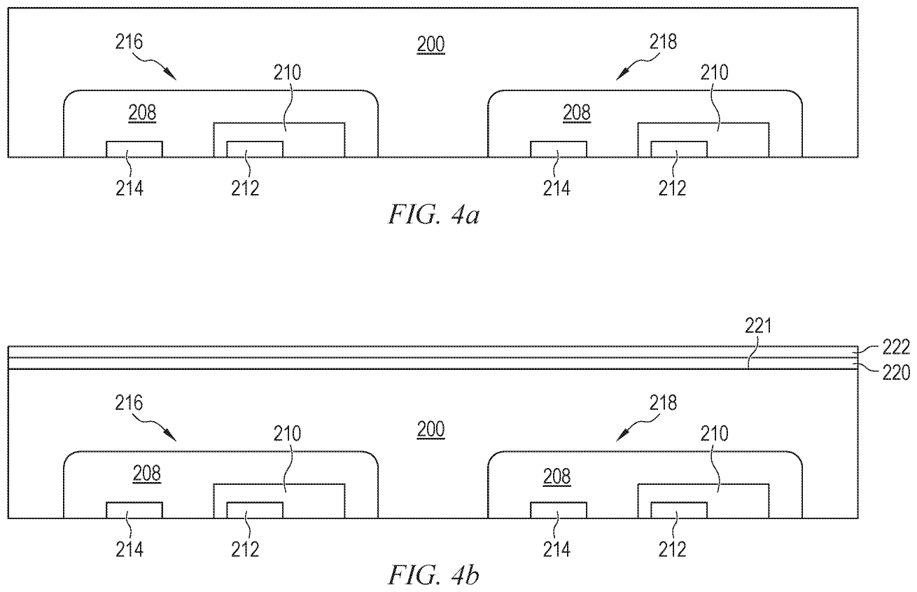

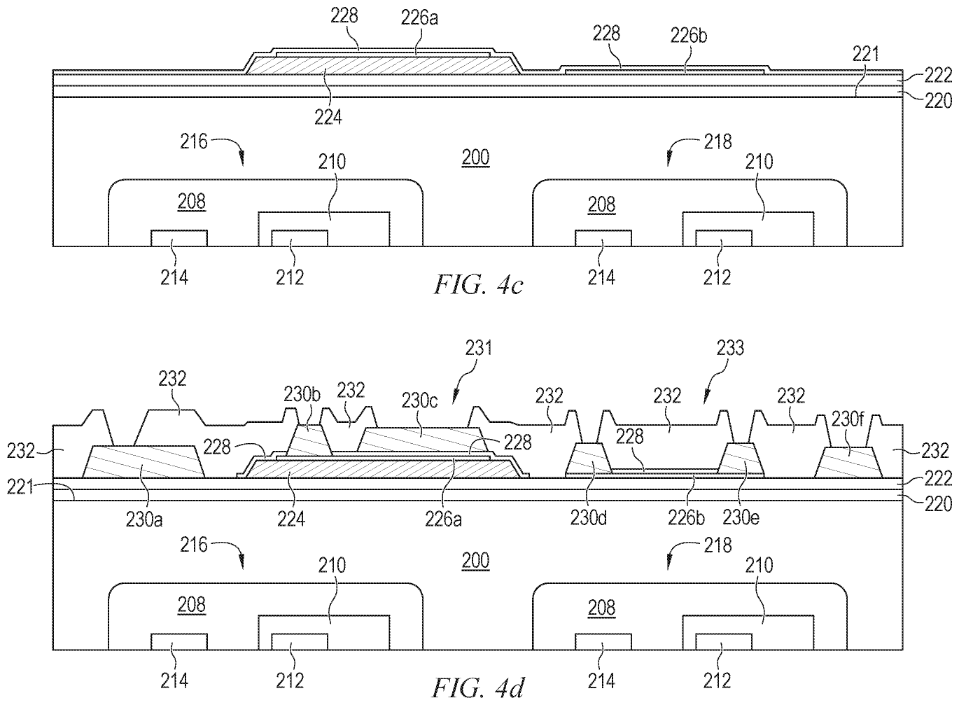

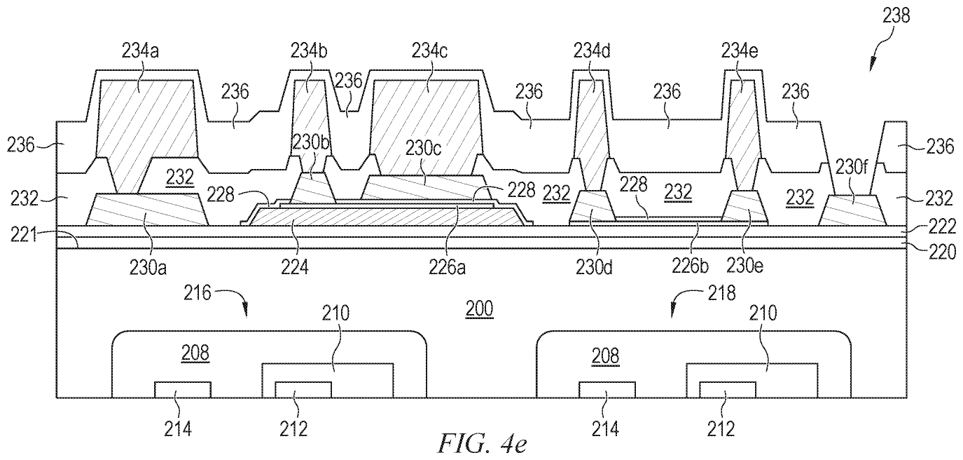

In another embodiment, FIG. 4a illustrates an active semiconductor device, e.g., a bipolar transistor, formed within low-resistivity semiconductor wafer 200. In one embodiment semiconductor wafer 200 includes silicon with a low resistivity of 10 ohm-cm. N-type semiconductor region 208 represents a collector region, p-type semiconductor region 210 represents a base region, n-type semiconductor region 212 represents an emitter region, and region 214 can be a collector contact of NPN bipolar transistors 216 and 218. Alternatively, PNP transistors, as well as other active devices, can be formed in wafer 200.

In FIG. 4b, insulating or passivation layer 220 is formed over surface 221 of semiconductor wafer 200 using PVD, CVD, printing, lamination, spin coating, spray coating, sintering or thermal oxidation. Insulating layer 220 contains one or more layers of SiO2, Si3N4, SiON, Ta2O5, Al2O3, solder resist, polyimide, BCB, PBO, and other material having similar insulating and structural properties. In one embodiment, insulating layer 220 is oxide. Insulating layer 220 provides isolation from surface 222.

An insulating or passivation layer 222 is formed over insulating layer 220 using PVD, CVD, printing, lamination, spin coating, spray coating, sintering or thermal oxidation. Insulating layer 222 contains one or more layers of SiO2, Si3N4, SiON, Ta2O5, Al2O3, solder resist, polyimide, BCB, PBO, and other material having similar insulating and structural properties.

In FIG. 4c, conductive layer 224 is formed over insulating layer 222 and surface 221 of semiconductor wafer 200 using PVD, CVD, electrolytic plating, electroless plating process, or other suitable metal deposition process. Conductive layer 224 can be one or more layers of Al, Cu, Sn, Ni, Au, Ag, or other suitable electrically conductive material. Conductive layer 224 operates as an M-cap base layer, i.e., a bottom electrode of subsequently formed capacitor.

A resistive layer 226 is formed over conductive layer 224 and insulating layer 222. Resistive layer 226 can be TaSi2 or other metal silicides, TaN, NiCr, TiN, or doped poly-silicon. The deposition of resistive layer 226 involves PVD or CVD with a thickness matching a designed surface resistivity. Portions of resistive layer 226 are removed, leaving resistive layer 226a and 226b, as shown.

An insulating or passivation layer 228 is formed over insulating layer 222, conductive layer 224, and resistive layer 226 using PVD, CVD, printing, lamination, spin coating, spray coating, sintering or thermal oxidation. Insulating layer 228 contains one or more layers of SiO2, Si3N4, SiON, Ta2O5, Al2O3, solder resist, polyimide, BCB, PBO, and other material having similar insulating and structural properties. In one embodiment, insulating layer 228 is nitride.

In FIG. 4d, portions of insulating layer 228 are removed to expose conductive layer 224 and insulating layer 222, as shown. Conductive layer 230 is formed over insulating layer 222, resistive layer 226, and insulating layer 228 using PVD, CVD, electrolytic plating, electroless plating process, or other suitable metal deposition process. Conductive layer 230 can be one or more layers of Al, Cu, Sn, Ni, Au, Ag, or other suitable electrically conductive material. Portions of conductive layer 230 can be electrically common or electrically isolated depending on the design and function of semiconductor die and other electrical components attached thereto. In particular, conductive layer 230a is formed over insulating layer 222, conductive layer 230b is formed over resistive layer 226a through an opening in insulating layer 228, conductive layer 230c is formed over insulating layer 228, and conductive layer 230d and 230e is formed over resistive layer 226b through an opening in insulating layer 228. The combination of conductive layer 230c, insulating layer 228, resistive layer 226a, and M-cap conductive layer 224 constitute capacitor or IPD 231. The combination of conductive layer 230d, resistive layer 226b, and conductive layer 230e constitute resistor 233. A portion of conductive layer 230 can be wound into a spiral to have inductive properties. Accordingly, one or more IPD are formed over surface 221 of semiconductor wafer 200.

An insulating or passivation layer 232 is formed over insulating layer 222 and conductive layer 230 using PVD, CVD, printing, lamination, spin coating, spray coating, sintering or thermal oxidation. Insulating layer 232 contains one or more layers of SiO2, Si3N4, SiON, Ta2O5, Al2O3, solder resist, polyimide, BCB, PBO, and other material having similar insulating and structural properties. Insulating layer 232 provides isolation around conductive layer 230. Portions of insulating layer 232 are removed to expose conductive layer 230 for further electrical interconnect.

In FIG. 4e, conductive layer 234 is formed over conductive layer 230 and insulating layer 232 using PVD, CVD, electrolytic plating, electroless plating process, or other suitable metal deposition process. Conductive layer 234 can be one or more layers of Al, Cu, Sn, Ni, Au, Ag, or other suitable electrically conductive material. Portions of conductive layer 234 can be electrically common or electrically isolated depending on the design and function of semiconductor die and other electrical components attached thereto. In particular, conductive layer 234a is formed over and electrically connected to conductive layer 230a, conductive layer 234b is formed over and electrically connected to conductive layer 230b, conductive layer 234c is formed over and electrically connected to conductive layer 230c, conductive layer 234d is formed over and electrically connected to conductive layer 230d, and conductive layer 234e is formed over and electrically connected to conductive layer 230e.

An insulating or passivation layer 236 is formed over insulating layer 232 and conductive layer 234 using PVD, CVD, printing, lamination, spin coating, spray coating, sintering or thermal oxidation. Insulating layer 236 contains one or more layers of SiO2, Si3N4, SiON, Ta2O5, Al2O3, solder resist, polyimide, BCB, PBO, and other material having similar insulating and structural properties. Insulating layer 236 provides isolation around conductive layer 234. Portions of insulating layer 236 are removed to expose conductive layer 234 for further electrical interconnect.

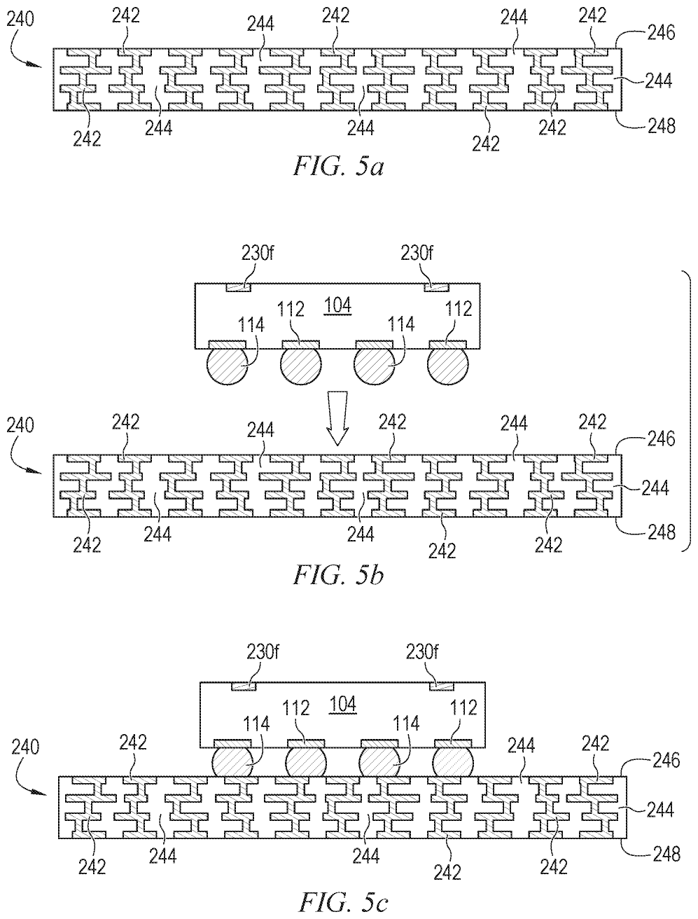

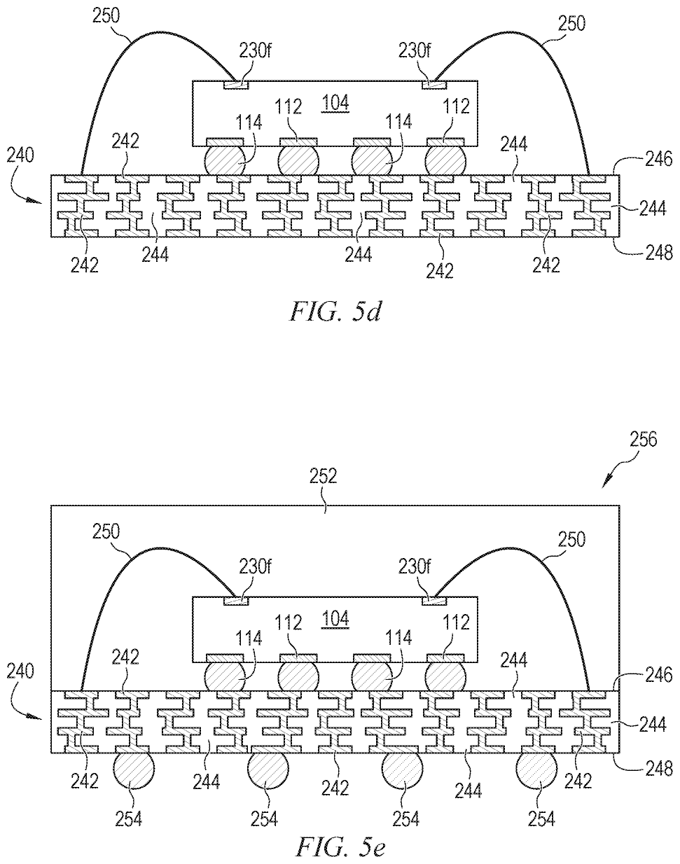

FIG. 5a shows a cross-sectional view of interconnect substrate 240 including conductive layers 242 and insulating layers 244. Conductive layers 242 can be one or more layers of Al, Cu, Sn, Ni, Au, Ag, or other suitable electrically conductive material. Conductive layers can be formed using PVD, CVD, electrolytic plating, electroless plating process, or other suitable metal deposition process. Conductive layers 242 provide horizontal electrical interconnect across substrate 240 and vertical electrical interconnect between top surface 246 and bottom surface 248 of substrate 240. Portions of conductive layers 242 can be electrically common or electrically isolated depending on the design and function of semiconductor die 104 and other electrical components. Insulating layers 244 contain one or more layers of SiO2, Si3N4, SiON, Ta2O5, Al2O3, solder resist, polyimide, BCB, PBO, and other material having similar insulating and structural properties. Insulating layers can be formed using PVD, CVD, printing, lamination, spin coating, spray coating, sintering or thermal oxidation. Insulating layers 244 provides isolation between conductive layers 242.

In FIG. 5b, semiconductor die 104 from FIG. 1a-1b incorporates hybrid substrate 238 from FIG. 4e. That is, hybrid substrate 238 includes a single substrate 200 with active devices formed within the substrate and one or more IPDs formed over one side of the hybrid substrate, as described in FIGS. 4a-4e.

In FIG. 1c, semiconductor wafer 100 is singulated through saw street 106 using a saw blade or laser cutting tool 118 into individual semiconductor die 104 containing hybrid substrate 238. The individual semiconductor die 104 can be inspected and electrically tested for identification of known good die or known good unit (KGD/KGU) post singulation.

Semiconductor die 104, with IPD formed on surface 221, is disposed on surface 246 of interconnect substrate 240 and electrically and mechanically connected to conductive layers 242. Semiconductor die 104 is positioned over substrate 240 using a pick and place operation with bumps 114 oriented toward surface 246 of substrate 240.

Semiconductor die 104 is brought into contact with surface 246 of interconnect substrate 240. FIG. 5c illustrates semiconductor die 104 electrically and mechanically connected to conductive layers 242 of substrate 240.

In FIG. 5d, bond wires 250 are attached between conductive layer 230f from FIG. 4e and conductive layer 242. Bond wires 250 provide electrical interconnect for IPDs like 231 and 233 formed over surface 221.

In FIG. 5e, an encapsulant or molding compound 252 is deposited over and around semiconductor die 104, bond wires 250, and interconnect substrate 240 using a paste printing, compressive molding, transfer molding, liquid encapsulant molding, vacuum lamination, spin coating, or other suitable applicator. Encapsulant 252 can be polymer composite material, such as epoxy resin with filler, epoxy acrylate with filler, or polymer with proper filler. Encapsulant 252 is non-conductive, provides structural support, and environmentally protects the semiconductor device from external elements and contaminants.

An electrically conductive bump material is deposited over conductive layer 242 on surface 248 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 242 using a suitable attachment or bonding process. In one embodiment, the bump material is reflowed by heating the material above its melting point to form balls or bumps 196. In one embodiment, bump 254 is formed over a UBM having a wetting layer, barrier layer, and adhesive layer. Bump 254 can also be compression bonded or thermocompression bonded to conductive layer 242. In one embodiment, bump 254 is a copper core bump for durability and maintaining its height. Bump 196 represents one type of interconnect structure that can be formed over conductive layer 242. The interconnect structure can also use bond wires, conductive paste, stud bump, micro bump, or other electrical interconnect.

The combination of interconnect substrate 240 and semiconductor die 104 with IPD formed on one side of the die constitute semiconductor package 256. Within semiconductor package 256, bond wires 250, conductive layers 230 and 234, interconnect substrate 240, and bumps 254 provide electrical interconnect for IPDs like 231 and 233 formed over surface 221. Bumps 114, interconnect substrate 240, and bumps 254 provide electrical interconnect for transistors 216 and 218, as well as other active devices formed within surface 110 of semiconductor wafer 100. Hybrid substrate 238 in semiconductor package 256 uses one semiconductor wafer 200 to form IPDs on one side of the wafer, thus reducing the number of wafers needed, as compared to the prior art described in the background. Reducing the number of wafers needed to form IPDs reduces manufacturing costs.

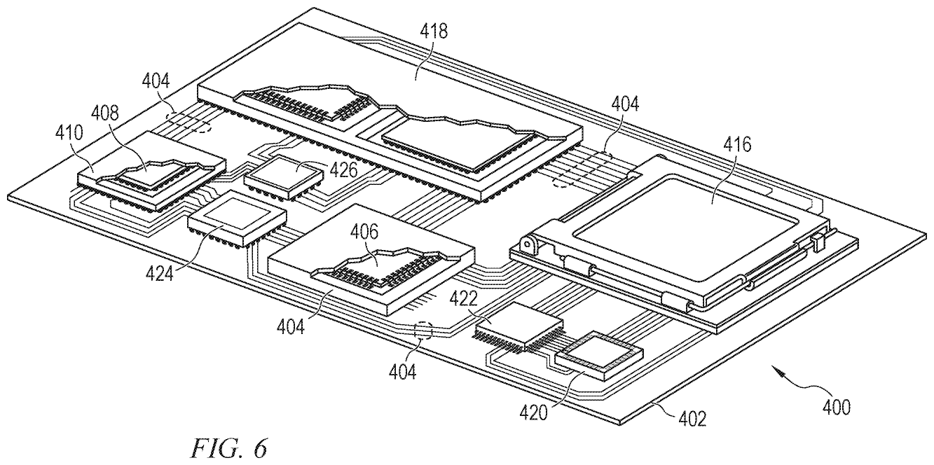

FIG. 6 illustrates electrical device 400 having a chip carrier substrate or PCB 402 with a plurality of semiconductor packages disposed on a surface of PCB 402, including semiconductor packages 198 and 256. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor wafer;
forming an insulating layer over the semiconductor wafer; and
forming a first integrated passive device (IPD) over the insulating layer.

2. The method of claim 1, wherein the first IPD includes a capacitor, resistor, or inductor.

3. The method of claim 1, further including forming a second IPD over a second surface of the semiconductor wafer opposite the first surface of the semiconductor wafer.

4. The method of claim 1, further including forming an interconnect structure over the first IPD.

5. The method of claim 4, further including:
singulating the semiconductor wafer to provide a semiconductor die comprising the first IPD;
disposing the semiconductor die over an interconnect substrate; and
forming a bond wire between the interconnect structure and the interconnect substrate.

6. The method of claim 1, further including forming an active device in a second surface of the semiconductor wafer opposite the first surface of the semiconductor wafer.

7. A method of making a semiconductor device, comprising:
providing a semiconductor wafer; and
forming a first integrated passive device (IPD) above a first surface of the semiconductor wafer.

8. The method of claim 7, wherein the first IPD includes a capacitor, resistor, or inductor.

9. The method of claim 7, wherein the semiconductor wafer has a low resistivity.

10. The method of claim 7, further including forming a second IPD over a second surface of the semiconductor wafer opposite the first surface of the semiconductor wafer.

11. The method of claim 7, further including forming an interconnect structure over the first IPD.

12. The method of claim 11, further including:
singulating the semiconductor wafer to provide a semiconductor die comprising the first IPD;
disposing the semiconductor die over an interconnect substrate; and
forming a bond wire between the interconnect structure and the interconnect substrate.

13. The method of claim 7, further including forming an active device in a second surface of the semiconductor wafer opposite the first surface of the semiconductor wafer.

14. A semiconductor device, comprising:
a semiconductor wafer including a plurality of semiconductor die;
an insulating layer formed over the semiconductor wafer; and
a first integrated passive device (IPD) formed over the insulating layer.

15. The semiconductor device of claim 14, wherein the first IPD includes a capacitor, resistor, or inductor.

16. The semiconductor device of claim 14, further including a second IPD formed over a second surface of the semiconductor wafer opposite the first surface of the semiconductor wafer.

17. The semiconductor device of claim 14, further including an interconnect structure formed over the first IPD.

18. The semiconductor device of claim 17, further including:
an interconnect substrate, wherein the semiconductor die is disposed over the interconnect substrate; and
a bond wire formed between the interconnect structure and the interconnect substrate.

19. The semiconductor device of claim 14, further including an active device formed in a second surface of the semiconductor wafer opposite the first surface of the semiconductor wafer.

20. A semiconductor device, comprising:
a semiconductor wafer including a plurality of semiconductor die; and
a first integrated passive device (IPD) above a first surface of the semiconductor die.

21. The semiconductor device of claim 20, wherein the first IPD includes a capacitor, resistor, or inductor.

22. The semiconductor device of claim 20, further including a second IPD formed over a second surface of the semiconductor die opposite the first surface of the semiconductor die.

23. The semiconductor device of claim 20, further including an interconnect structure formed over the first IPD.

24. The semiconductor device of claim 20, further including:
an interconnect substrate, wherein the semiconductor die is disposed over the interconnect substrate; and
a bond wire formed between the interconnect structure and the interconnect substrate.

25. The semiconductor device of claim 20, further including an active device formed in a second surface of the semiconductor die opposite the first surface of the semiconductor die.
